(19) United States
(12) Patent Application Publication
(10) Pub. No.: US 2023/0023458 A1
(43) Pub. Date: Jan. 26, 2023

(54) MASK AND MASK ASSEMBLY

(71) Applicant: HEFEI VISIONOX TECHNOLOGY CO., LTD., Hefei (CN)

(72) Inventors: Enxia WANG, Hefei (CN); Lin SUN, Hefei (CN); Shitai LI, Hefei (CN); Hui LI, Hefei (CN); Weili LI, Hefei (CN); Mingxing LIU, Hefei (CN); Shuaiyan GAN, Hefei (CN)

(73) Assignee: HEFEI VISIONOX TECHNOLOGY CO., LTD., Hefei (CN)

(21) Appl. No.: 17/957,399

(22) Filed: Sep. 30, 2022

Related U.S. Application Data
(63) Continuation of application No. PCT/CN2021/096672, filed on May 28, 2021.

(30) Foreign Application Priority Data
Aug. 31, 2020 (CN) 202010899158.2

(51) Int. Cl. C23C 14/04; C23C 14/24

(52) U.S. Cl. CPC C23C 14/042; C23C 14/24

(57) ABSTRACT

A mask and a mask assembly, which relates to the display field. The mask includes an opening region, a welding region and a blocking groove, the welding region is arranged around the opening region, and the blocking groove is arranged outside the opening area. When the mask is welded to a frame, wrinkles will appear on the mask. In embodiments of the present application, by providing a blocking groove on the mask, the spreading of the wrinkles may be blocked by the blocking groove, thereby preventing the wrinkles from extending into the opening region of the mask, avoiding the position shifting of the opening region, and improving the evaporation accuracy.

### CROSS-REFERENCE TO RELATED APPLICATIONS

This application is a continuation of International Application No. PCT/CN2021/096672, filed on May 28, 2021, which claims priority to Chinese Patent Application No. 202010899158.2 filed on Aug. 31, 2020. The disclosures of the aforementioned applications are hereby incorporated by reference in their entireties.

### TECHNICAL FIELD

The present application relates to the technical field of display, and in particular, to a mask and a mask assembly.

### BACKGROUND

The film structure of Organic Light-Emitting Diode (OLED) usually needs to be formed by evaporation using a mask assembly.

The mask assembly usually includes a frame and a mask, where the mask includes an opening region and a welding region arranged around the opening region, and an alignment hole is arranged in the welding region. During the forming of the mask assembly, it is often necessary to place the mask on the frame first, align the alignment hole of the mask with the alignment hole of the frame, and then weld the welding region of the mask on the frame.

However, during welding, wrinkles appear in the welding region, and these wrinkles will extend into the opening region, causing the position of an opening in the opening region to shift, which affects the accuracy of evaporation.

### SUMMARY

In view of the above problems, embodiments of the present application provide a mask and a mask assembly, for preventing extension of wrinkles of the mask, which avoids the position shifting of an opening of the mask, and improves evaporation accuracy.

For achieving the above purposes, embodiments of the present application provide the following technical solutions.

A first aspect of the embodiments of the present application provides a mask, including an opening region, a welding region and a blocking groove, the welding region is arranged around the opening region, and the blocking groove is arranged outside the opening region and configured to prevent wrinkles, caused by welding the mask to a frame, from extending into the opening region.

A second aspect of the embodiments of the present application provides a mask assembly, including a frame and the mask provided in the first aspect above, where the mask is welded to the frame.

For the mask and the mask assembly provided by the embodiments of the present application, when the mask is welded to the frame, wrinkles will form on the mask. In the embodiments of the present application, by arrangement of the blocking groove on the mask, the blocking groove may block the spreading of wrinkles and prevent the wrinkles from extending into the opening region of the mask, thereby avoiding the position shifting of the opening region, and improving the evaporation accuracy.

In addition to technical problems solved by the embodiments of the present application, technical features constituting technical solutions, and beneficial effects brought about by the technical features of these technical solutions described above, other technical problems which can be solved by the mask and the mask assembly according to the embodiments of the present application, other technical features included in the technical solutions, and the beneficial effects brought about by these technical features will be described in further detail in the specific embodiments.

### BRIEF DESCRIPTION OF THE DRAWINGS

FIG. 1 is a structural schematic diagram of a mask according to an embodiment of the present application.

FIG. 2 is a first structural schematic diagram of a mask assembly according to an embodiment of the present application.

FIG. 3 is a front view of FIG. 2.

FIG. 4 is a diagram of wrinkles distribution on a mask according to an embodiment of the present application.

FIG. 5 is a second schematic structural diagram of a mask assembly according to an embodiment of the present application.

FIG. 6 is a third structural schematic diagram of a mask assembly according to an embodiment of the present application.

FIG. 7 is a fourth structural schematic diagram of a mask assembly according to an embodiment of the present application.

FIG. 8 is a fifth structural schematic diagram of a mask assembly according to an embodiment of the present application.

FIG. 9 is a front view of FIG. 8.

FIG. 10 is a structural schematic diagram of a frame according to an embodiment of the present application.

### DETAILED DESCRIPTION OF THE EMBODIMENTS

During the process of actual operation, the inventor of the present application found that in the process of placing a mask on a frame by a clamping jaw and welding the mask to the frame by laser welding, stress will be formed inside the mask. When the stress is focused on some areas of the mask, such as an area where alignment holes are located, wrinkles will occur in these areas. During a subsequent evaporation and alignment process, the above-mentioned wrinkles will be expanded by magnetic adsorption and extend into an opening region of the mask, which causes position shifting of the opening region and reduces the Pixel Position Accuracy (PPA) of evaporation, thereby leading to the pixel deviation of a vapor-deposited OLED device, and affecting the normal display of the OLED device.

In view of the above technical problems, embodiments of the present application provide a mask and a mask assembly. By providing a blocking groove on the mask, when the wrinkles on the mask plate extend to the blocking groove, the blocking groove may block the spreading of the wrinkles and prevent the wrinkles from entry into the opening region of the mask, thereby avoiding the position shifting of the opening region, and improving evaporation accuracy.

Hereinafter, the technical solutions in the embodiments of the present application are clearly and completely described with reference to the accompanying drawings.

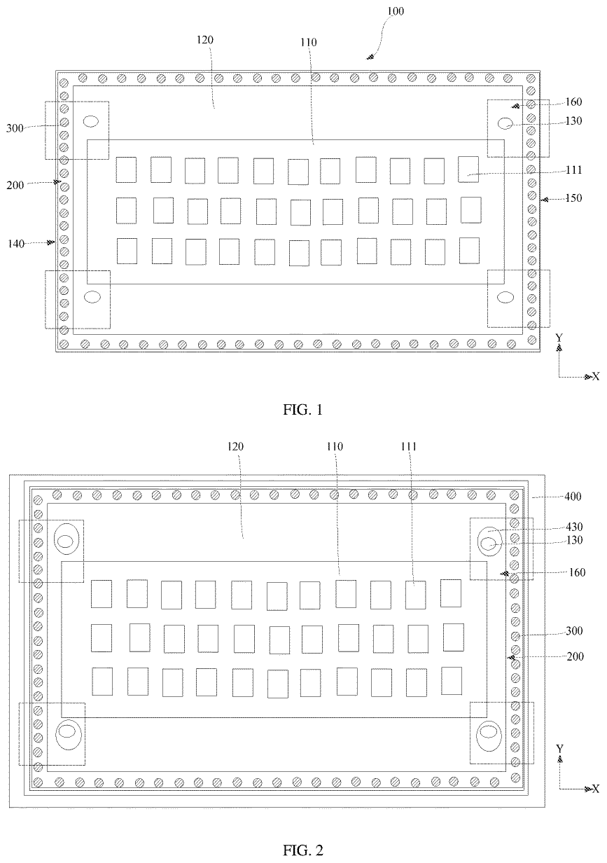

As shown in FIGS. 1, a mask 100 according to an embodiment of the present application includes an opening region 110, and a welding region 120 arranged around the opening region 110. A blocking groove 200 is disposed between the welding region 120 and the opening region 110, that is, the blocking groove 200 is provided at the periphery of the opening region 110. The blocking groove 200 serves to prevent the wrinkles caused by the welding of the mask 100 and a frame from extending into the opening region 110.

Herein, the opening region 110 includes a plurality of openings 111 arranged in an array, respective openings 111 corresponding to different display areas of the display panel to be prepared, and the purpose of dividing a display panel into different display areas may be achieved by the plurality of openings.

In addition, the part of the mask 100 except the opening region 110 is the welding region 120. Before evaporation, the welding region 120 of the mask 100 needs to be welded to the frame by a laser welding machine. As shown in FIG. 2, FIG. 2 is a structural schematic diagram of a mask assembly obtained after the welding is completed.

In the process of welding the mask to the frame, two processes of stretching and flattening the mask and welding the mask are included. In the two processes, wrinkles will appear on the mask due to concentration of stress, and such wrinkles will extend into the opening region, thereby causing the position of the opening region to shift. Therefore, in this embodiment of the present application, the blocking groove 200 is provided between the opening region 110 and the welding region 120 and is configured to block the wrinkles generated when the mask and the frame are welded from extending into the opening region 110, thereby avoiding the position shift of the openings 111 in the opening region 110, and improving the evaporation accuracy. In addition, since the evaporation accuracy is improved, the area of shade due to evaporation is also reduced, which can ensure the uniformity of thickness of an evaporation film.

For a welding process, stress concentration will appear around welding joints, and the stress tends to lead to the formation of wrinkles at the positions of the mask corresponding to the welding joints. Therefore, in this embodiment, the blocking groove 200 may be configured to accommodate the welding joints used in welding the mask 100 to the frame 400, that is, the blocking groove may be formed in the welding region 120 of the mask 100. When the mask 100 needs to be welded to the frame 400, the mask 100 is firstly placed on the frame 400 using a clamping jaw, then the welding joints 300 are formed in the blocking groove using laser welding and the mask 100 is welded to the frame 400 through the welding joints 300.

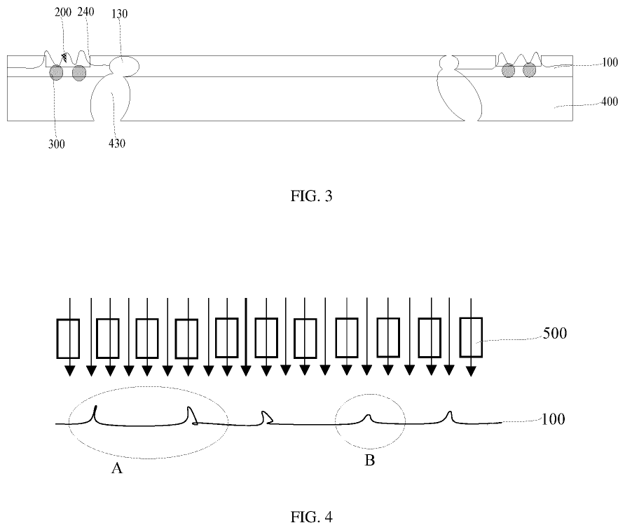

In this embodiment, as shown in FIG. 3, a height of the welding joints 300 is smaller than a depth of the blocking groove 200, in such a manner that when the wrinkles caused by welding extend to the opening region 110 of the mask, the wrinkles will preferentially meet side walls 240 of the blocking groove 200. In this way, the side walls 240 of the blocking groove 200 will block the extension of the wrinkles and prevent the wrinkles from entry to the opening region 110 of the mask 100, thereby preventing the position of the opening region 110 from shifting, and improving the evaporation accuracy.

It should be noted that an arrangement of the blocking groove 200 is consistent with a layout of the welding joints 300. For example, as shown in FIG. 2, the welding joints 300 are spaced along the edge of a rectangular mask 100 to form a ring-shaped welding structure. Correspondingly, the blocking groove 200 formed on the mask 100 is also a ring-shaped blocking groove 200, that is to say, the extending direction of the blocking groove 200 is consistent with the edge of the mask 100. The top view of the blocking groove 200 is rectangular.

During its use, the mask 100 needs to be transported by a transmission device, cleaned and dried. During the above process, the mask 100 will be subjected to vibration or blowing with a cleaning wind, which may easily cause the welding joints 300 to loosen and fall off. Therefore, this embodiment adopts the ring-shaped welding structure, so that each edge of the mask 100 is evenly provided with a plurality of the welding points 300. This design can improve the connection stability between the mask 100 and the frame 400. While the risk of the welding joints 300 peeling is reduced, the service life and stability of the mask 100 may also be improved.

Further, in order to ensure position accuracy between the mask 100 and the frame 400 and thus make the mask 100 accurately attached to the frame 400, an alignment hole 130 is also provided in the welding region 120 of the mask 100 provided in this embodiment, and an area where the alignment hole 130 is located may be called as an alignment region 160. Correspondingly, the frame 400 is also provided with a reference hole 430 corresponding to the alignment hole 130.

It should be noted that the setting of the alignment hole 130 is intended to facilitate the accurate fixing of the mask 100 on the frame 400, and to facilitate an evaporation machine to accurately identify a range of evaporation needed. Therefore, in order to improve the alignment accuracy between the mask 100 and the frame 400, multiple alignment holes 130 may be arranged. For example, as shown in FIG. 2, the mask 100 is rectangular, the number of the alignment holes 130 may be four. Four of the alignment holes 130 are respectively arranged at four corners of the rectangular mask 100, so that the evaporation machine needs to align all the four alignment holes 130 during an alignment process, which can improve the alignment accuracy between the mask 100 and the frame 400, thereby improving the evaporation accuracy of the mask 100.

When the mask 100 is welded to the frame 400 by laser welding, the stress will appear inside the mask plate 100, causing the wrinkles to form on the mask 100. However, in the actual process, such stress is usually preferentially concentrated in the area where the alignment holes 130 are located, causing the wrinkles in the area where the alignment holes 130 are located will be larger than those in other areas. As shown in FIG. 4, the wrinkles in the area A corresponding to the alignment holes 130 will be larger than those in the area B corresponding to the opening region 110.

In a subsequent evaporation alignment process, a magnetic force of a magnet plate 500 will need to be used to tightly adsorb the mask on the frame. Therefore, the magnetic adsorption will cause the wrinkles in the area where the alignment hole is located to expand, and the wrinkles in the area where the alignment hole is located will extend into the opening region of the mask, causing the position of the opening region to shift and reducing the Pixel Position Accuracy (PAA) of evaporation, thereby causing the pixel shift of a vapor-deposited OLED device, and affecting the normal display of the OLED device.

Therefore, the blocking groove 200 may be selectively disposed near the alignment holes 130, that is, the blocking groove 200 may surround part of the alignment holes 130. It can be understood that, taking the orientation shown in FIG. 2 as an example, the surrounding in this embodiment means that when the mask 100 is a rectangular parallelepiped, projections of the alignment holes 130 on a left side wall of the mask 100 are within a projection of the blocking groove 200 on the left side wall. At the same time, a vicinity of the alignment holes 130 may be understood as a space between the alignment holes 130 and a left edge of the mask 100, or a space between the alignment holes 130 and an upper edge of the mask 100, or a space between the alignment holes 130 and the right edge of the mask 100.

In addition, during the alignment process of an alignment mechanism of the evaporation machine, since the welding joints 300 which are adjacent to the alignment holes 130 are arranged in the blocking groove 200 and the height of the welding joints 300 is smaller than the depth of the blocking groove, the welding joints 300 will not be misidentified as the alignment holes 130, which may improve the alignment accuracy, thereby enhancing the evaporation accuracy.

It should be noted that the depth of the blocking groove 200 may be freely designed according to the height of the welding joints 300 and a thickness of the mask 100, where a ratio of the depth of the blocking groove 200 to the thickness of the mask 100 is between 0.3 and 0.5.

For example, when the thickness of the mask 100 is 100 μm, the depth of the blocking groove 200 may be from 20 μm to 30 μm and the height of the welding joints 300 may be less than or equal to 10 μm.

Therefore, in the embodiment of the present application, the blocking groove 200 is arranged in the vicinity of the alignment holes 130, and the blocking groove 200 surrounds part of the alignment holes 130. The spreading of wrinkles are blocked by a height difference between the blocking groove 200 and the surface of the mask plate 100, which prevents the wrinkles from spreading into the opening region, thereby improving the evaporation accuracy.

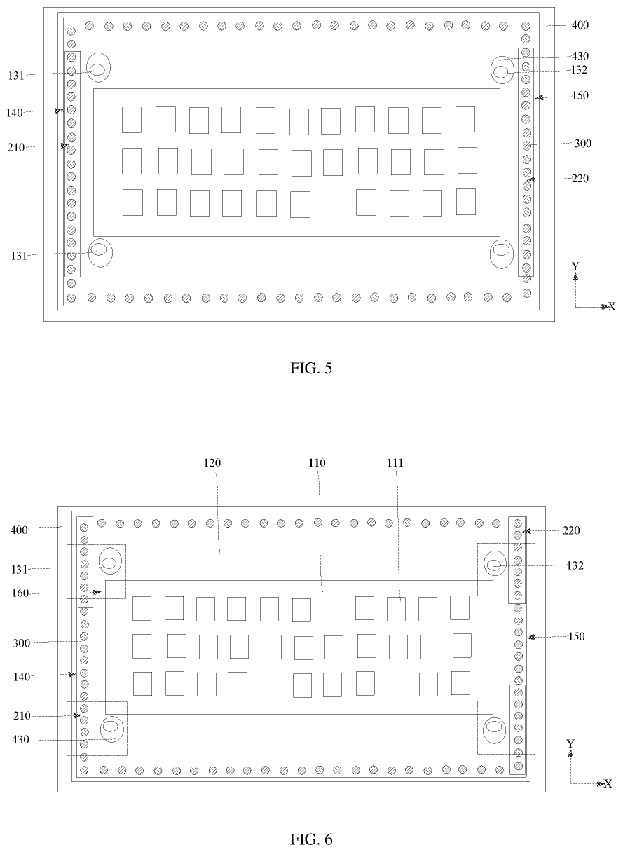

In some embodiments, as shown in FIG. 5, the mask 100 is rectangular, and along the length direction of the mask 100, that is, the X direction in FIG. 5, the mask 100 has a first edge 140 and a second edge 150 that are arranged oppositely. Taking a direction shown in FIG. 5 as an example, the first edge 140 is a left edge of the mask 100, and the second edge 150 is a right edge of the mask 100.

The alignment hole 130 includes a plurality of first alignment holes 131 and a plurality of second alignment holes 132, the plurality of the first alignment holes 131 are provided between the first edge 140 and the opening region 110 and arranged at intervals along an extending direction of the first edge 140, and the plurality of the second alignment holes 132 are provided between the second edge 150 and the opening region 110 and arranged at intervals along an extending direction of the second edge 150.

In this embodiment, the alignment accuracy of the mask 100 may be improved by the arrangement of the plurality of the first alignment holes 131 and the plurality of the second alignment holes 132. As for the number of the first alignment holes 131, the number of the first alignment holes 131 may be may be two, three, or more, which is not limited in this embodiment, provided that the precise alignment of the mask may be achieved.

Correspondingly, the blocking groove 200 may also include a first blocking groove 210 and a second blocking groove 220. The first blocking groove 210 is provided between the first edge 140 and the first alignment holes 131, the second blocking groove 220 is provided between the second edge 150 and the second alignment holes 132, and a length direction of the first blocking groove 210 and a length direction of the second blocking groove 220 are both parallel to a width direction of the mask 100.

In this embodiment, a structure of the first blocking groove 210 may be the same as a structure of the second blocking groove 220. For the convenience of description, the following descriptions take the first blocking groove 210 as an example.

For example, when the number of the first alignment holes 131 is two, the number of the first blocking groove 210 may be one. As shown in FIG. 5, the first blocking groove 210 is a rectangular groove, and projections of the two first alignment holes 131 on the left side wall of the mask 100 are each located in a projection of the first blocking groove 210 on the left side wall.

For another example, the number of the first blocking grooves 210 is two, as shown in FIG. 6, the two first blocking grooves 210 are distributed at intervals along the width direction of the mask 100 and correspond to the two first alignment holes 131 one-to-one. That is to say, a projection of one of the first alignment holes 131 on the left side wall of the mask 100 is located in the projection of the corresponding one of the first blocking grooves 210 on the left side wall, and a projection of the other first alignment hole 131 on the left side wall of the mask 100 is located in the projection of the corresponding other first blocking groove 210 on the left side wall.

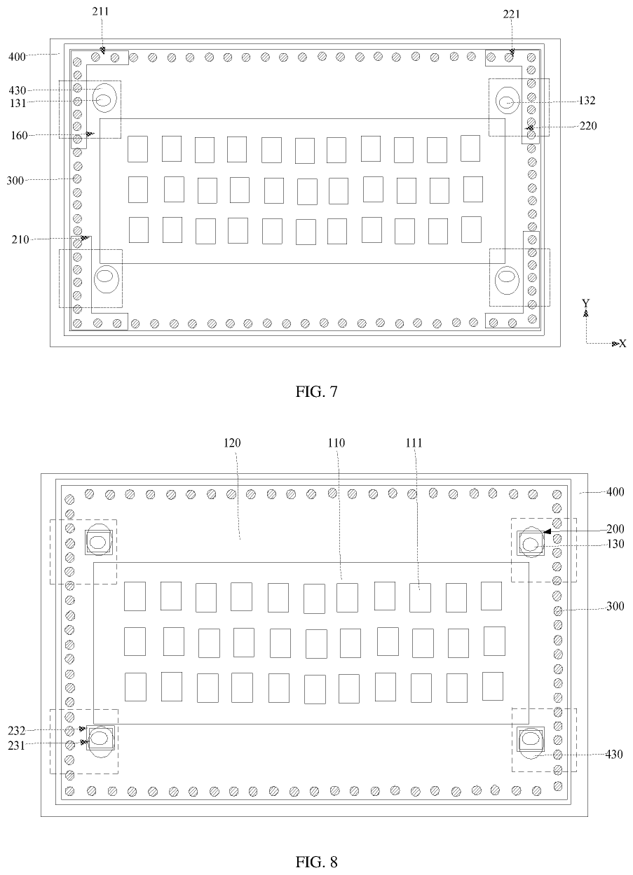

In some embodiments, along the length of the first blocking groove 210, that is, along the Y direction in FIG. 7, at least one end of the first blocking groove 210 is bent toward the second blocking groove 220 to form a first bending section 211. Similarly, along the length direction of the second blocking groove 220, at least one end of the second blocking groove 220 is bent toward the first blocking groove 210 to form a second bending section 221.

It should be noted that, in this embodiment, only one of the first bending segment 211 and the second bending segment 221 may be provided, or they may be provided at the same time.

The shapes of the first blocking groove 210 and the second blocking groove 220 are L-shaped or U-shaped, which may increase the areas of the first blocking groove 210 and the second blocking groove 220, and prevent the wrinkles around the alignment holes 130 from spreading into the opening region 110 of the mask 100, thereby avoiding the position shift of the opening 111 in the opening region 110 and improving the evaporation accuracy.

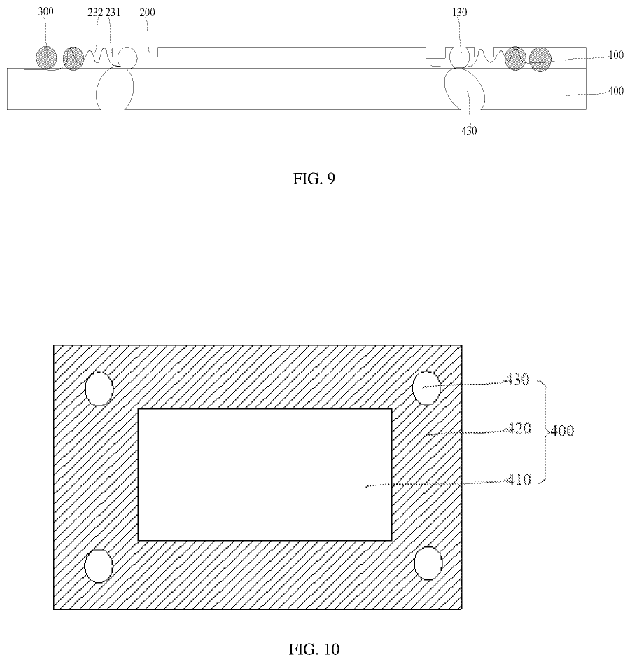

In some embodiments, as shown in FIG. 8 and FIG. 9, the welding region 120 is further provided with the alignment holes 130, which are configured for aligning with the reference holes 430 of the frame 400, and the blocking grooves 200 surround at least part of the alignment holes 130. That is, the blocking grooves 200 are only arranged around the alignment holes 130, and there is no need to set the welding joints 300 in the blocking grooves 200, which facilitates a fixed connection between the mask and the frame, and improves an operation convenience.

It should be understood that the term “surround” in this embodiment may be understood as that part of the alignment holes 130 are located in the areas enclosed by the blocking grooves 200, or all the alignment holes 130 are located in the areas enclosed by the blocking grooves 200.

Further, the blocking groove 200 may include a plurality of blocking sub-grooves, and the plurality of blocking sub-grooves are distributed at intervals along edges of the alignment holes 130, so that when the wrinkles generated during the welding process are spread into the blocking sub-grooves, the wrinkles will be blocked by side walls of the blocking sub-grooves, thereby preventing the wrinkles from entry into the opening region 110, avoiding the shifting of opening position in the opening region, and improving the evaporation accuracy.

The shape of the blocking sub-grooves may be selected in various ways, for example, the top view of the blocking sub-grooves may be rectangular or arc-shaped grooves, and arc centers of the arc-shaped grooves coincide with circle centers of the alignment holes.

In some embodiments, a plurality of blocking sub-grooves are communicated with each other so that the blocking groove 200 forms an annular structure. The blocking groove 200 has a first annular edge 231 and a second annular edge 232, the first annular edge 231 is close to the edge of the mask 100, and the alignment holes 130 are provided in the area enclosed by the first annular edge 231. That is to say, the blocking groove 200 of the annular structure surrounds the alignment holes 130, correspondingly, the top view of the blocking groove 200 may be a circular ring or square.

Further, the second annular edge 232 may overlap with the edge of the alignment holes 130, that is, the blocking groove 200 is communicated with the alignment holes 130, which may simplify the manufacturing process of the blocking groove 200.

Embodiments of the present application further provide a mask assembly, including a frame 400 and the above mask 100. The frame 400 may include an opening portion 410 and a border portion 420 surrounding the opening portion 410, and the opening portion 410 is configured to correspond to the opening region 110 of the mask 100, which facilitates an evaporation of an evaporated material onto a substrate to be evaporated, after the evaporated material passes through the opening portion 410 of the frame 400 and the opening region 110 of the mask 100.

As shown in FIG. 10, the frame 400 may include several borders, which are connected end to end in turn to form a closed frame, and an area enclosed by these borders is the opening portion.

It can be understood that the term “several” mentioned in this embodiment refers to two or more. For example, the frame provided in this embodiment includes four rectangular borders, and the four borders are connected end to end in turn to form a rectangular frame, and adjacent borders may be connected together by welding or plugging-in.

In addition, the frame in this embodiment may also be integrally-formed one-piece part, so as to increase the strength of the frame, thereby prolonging the service life of the frame.

In order to ensure a structural strength and a service life of the frame 400, the frame 400 may be made of a metal material, so that the frame 400 is capable of supporting the mask 100 and ensuring the normal operation of the evaporation process.

In addition, the border portion 420 of the frame 400, that is, the upper surfaces of respective borders, constitutes the welding region of the frame. The border portion 420 of the frame 400 is provided with reference holes 430 corresponding to the alignment holes 130 one-to-one, and the reference holes 430 are through-holes which penetrate through the frame 400, where the through-holes may be regular cylindrical holes or square holes, or irregular holes, which is not specifically limited in this embodiment.

During a process of making a mask assembly, a mask is usually placed on a frame by a clamping jaw, and the lower surface of the mask is attached to the border portion of the frame, and then the alignment holes on the mask are located just over the reference holes of the frame, and finally the welding region of the mask is welded to the border portion of the frame by laser welding

Since the mask plate 100 provided in this embodiment is provided with the blocking groove 200, when the mask is soldered, the wrinkles formed on the mask 100 will be blocked by the blocking groove 200 from extending into the opening region 110, thereby preventing the position of the opening 111 from shifting in the opening region 110, and improving the evaporation accuracy.

Furthermore, the mask needs to be transported by the transmission device, cleaned and dried during its use. During the above process, the mask will be subjected to vibration or blowing with a cleaning wind, which may easily cause the welding joints to loosen and fall off. Therefore, this embodiment adopts the ring-shaped welding structure, so that each edge of the mask is evenly provided with a plurality of the welding points. This design can improve the connection stability between the mask and the frame. While the risk of the welding joints peeling is reduced, the service life and stability of the mask may also be improved.

Finally, it should be noted that the above embodiments are only intended for illustrating rather than limiting the technical solutions of the present application; although the application has been described in detail with reference to the foregoing embodiments, those of ordinary skill in the art should understand that it is still possible to make a modification on the technical solutions recorded in the foregoing embodiments, or to perform equivalent replacements to some or all of the technical features. However, such modifications or replacements do not make the essence of the corresponding technical solutions deviate from the scope of the technical solutions of the embodiments of the present application.

What is claimed is:

1. A mask, comprising:
an opening region;
a welding region arranged around the opening region; and
a blocking groove arranged outside the opening region and configured to prevent wrinkles, caused by welding the mask to a frame, from extending into the opening region.

2. The mask according to claim 1, wherein a plurality of alignment holes for aligning with reference holes of the frame are further provided in the welding region, and the blocking groove at least surrounds part of the plurality of alignment holes.

3. The mask according to claim 2, wherein the blocking groove is configured to accommodate welding joints used in welding the mask to the frame, and a height of the welding joints is smaller than a depth of the blocking groove.

4. The mask according to claim 3, wherein the welding joints are distributed at intervals along an edge of the mask to form a ring-shaped welding structure, and the blocking groove is configured as a ring-shaped structure corresponding to the ring-shaped welding structure.

5. The mask according to claim 2, wherein the mask is rectangular and comprises a first edge and a second edge which are arranged oppositely along a length direction of the mask;
the plurality of alignment holes comprises a plurality of first alignment holes and a plurality of second alignment holes, the plurality of the first alignment holes are disposed between the first edge and the opening region, and the plurality of the first alignment holes are disposed at intervals along an extending direction of the first edge; and
the plurality of the second alignment holes are disposed between the second edge and the opening region, and the second alignment holes are disposed at intervals along an extending direction of the second edge.

6. The mask according to claim 5, wherein the blocking groove comprises a first blocking groove and a second blocking groove, the first blocking groove is provided between the first edge and the first alignment holes, the second blocking groove is provided between the second edge and the second alignment holes, and a length direction of the first blocking groove and a length direction of the second blocking groove are both parallel to a width direction of the mask.

7. The mask according to claim 6, wherein along the length direction of the first blocking groove, at least one end of the first blocking groove is bent toward the second blocking groove to form a first bending section; and/or
along the length direction of the second blocking groove, at least one end of the second blocking groove is bent toward the first blocking groove to form a second bending section.

8. The mask according to claim 2, wherein the blocking groove comprises a plurality of blocking sub-grooves, and the plurality of the blocking sub-grooves are distributed at intervals along edges of the plurality of alignment holes.

9. The mask according to claim 8, wherein the blocking sub-grooves are arc-shaped grooves, and arc centers of the arc-shaped grooves coincide with circle centers of the plurality of alignment holes.

10. The mask according to claim 9, wherein the blocking sub-grooves are communicated with each other to form the blocking groove as an annular structure.

11. The mask according to claim 10, wherein the blocking groove has a first annular shape edge and a second annular edge, the first annular edge is close to an edge of the mask, and the plurality of alignment holes are provided in an area enclosed by the first annular edge.

12. The mask according to claim 11, wherein the second annular edge overlaps with edges of the plurality of alignment holes to communicate the blocking groove with the plurality of alignment holes.

13. The mask according to claim 1, wherein a ratio of a depth of the blocking groove to a thickness of the mask is from 0.3 to 0.5.

14. The mask according to claim 1, wherein the opening region comprises a plurality of openings corresponding one-to-one with a display area of a display panel to be prepared, and the plurality of openings is arranged in an array.
